(19) United States
(12) Patent Application Publication
(10) Pub. No.: US 2009/0253265 A1
(43) Pub. Date: Oct. 8, 2009

(54) METHOD FOR FABRICATING SEMICONDUCTOR DEVICE AND SUBSTRATE PROCESSING APPARATUS

(75) Inventors: Yasuhiro Inokuchi, Toyama-shi (JP); Atsushi Moriya, Toyama-shi (JP)

Correspondence Address: BRUNDIDGE & STANGER, P.C., 1700 DIAGONAL ROAD, SUITE 330, ALEXANDRIA, VA, 22314, US

(73) Assignee: Hitachi Kokusai Electric, Inc.

(21) Appl. No.: 12/236,550

(22) Filed: Sep. 24, 2008

(30) Foreign Application Priority Data
May 27, 2007 (JP) 2008-138091
Oct. 1, 2007 (JP) 2007-257040

(51) Int. Cl. H01L 21/306

(52) U.S. Cl. 438/694; 438/706; 156/345.26; 118/663

(57) ABSTRACT

Provided is a method and a substrate processing apparatus for fabricating a semiconductor device by forming a film at a relatively high rate without etching an N⁺ substrate. In the method, a silicon substrate is loaded into a processing chamber in a first step. In a second step, at least a first silane-based gas and a first etching gas is supplied to the processing chamber while heating the semiconductor substrate. In a third step, at least a second silane-based gas and a second etching gas is supplied to the processing chamber while heating the semiconductor substrate.

### CROSS-REFERENCE TO RELATED PATENT APPLICATION

This U.S. non-provisional patent application claims priority under 35 U.S.C. § 119 of Japanese Patent Application Nos. 2007-257040, filed on Oct. 1, 2007, and 2008-138091, filed on May 27, 2008, in the Japanese Patent Office, the entire contents of which are hereby incorporated by reference.

### BACKGROUND OF THE INVENTION

1. Field of the Invention

The present invention relates to a method for fabricating a semiconductor device by forming first and second films on an N⁺ substrate using different gases for preventing the N⁺ substrate from being etched and growing the first and second films at a relatively high rate.

2. Description of the Prior Art

In fabricating a semiconductor device, a silicon or silicon-germanium film can be formed on a substrate through a conventional process by using SiH₄ gas as a film-forming gas and Cl₂ gas that exhibits good etching characteristics in a film-forming temperature range of SiH₄ as an etching gas. In another conventional process, SiH₂Cl₂ gas is used as a film-forming gas, and HCl gas is used as an etching gas. SiH₄ gas has superior film-forming ability to SiH₂Cl₂ gas since films can be formed with SiH₄ gas at a higher rate with less thermal defects owing to its lower processing temperature.

When Cl₂ gas is used as an etching gas, however, an N⁺ substrate can be undesirably etched. Additionally, in a process in which HCl gas is used as an etching gas to prevent etching of an N⁺ substrate, SiH₂Cl₂ gas needs to be used as a film-forming gas in a temperature range in which HCl gas exhibits good etching characteristics; and in a process in which Cl₂ is used as an etching gas, SiH₄ gas needs to be used as a film-forming gas in a temperature range in which Cl₂ gas exhibits good etching characteristics. However, film forming with SiH₂Cl₂ gas is slower than film forming with SiH₄ gas.

### SUMMARY OF THE INVENTION

Therefore, an object of the present invention is to provide a method for fabricating a semiconductor device by forming a film at a relatively high rate without etching an N⁺ substrate.

According to an aspect of the present invention, there is provided a method for fabricating a semiconductor device. The method includes: a first step of loading a silicon substrate into a processing chamber; a second step of supplying at least a first silane-based gas and a first etching gas to the processing chamber while heating the semiconductor substrate; and a third step of supplying at least a second silane-based gas and a second etching gas to the processing chamber while heating the semiconductor substrate.

According to another aspect of the present invention, there is provided a method for fabricating a semiconductor device. The method includes: a first step of loading a silicon substrate into a processing chamber; a second step of supplying at least a first silane-based gas and a first etching gas to the processing chamber while heating the semiconductor substrate; a third step of supplying at least a second silane-based gas to the processing chamber while heating the semiconductor substrate; and a fourth step of supplying at least a second etching gas to the processing chamber while heating the semiconductor substrate, wherein the third and fourth steps are repeated a plurality of times.

According to another aspect of the present invention, there is provided a substrate processing apparatus. The substrate processing apparatus includes: a processing chamber configured to accommodate a silicon substrate; a heater configured to heat the silicon substrate; a plurality of gas supply units configured to supply silane-based gas and etching gas to the processing chamber; an exhaust unit configured to exhaust the processing chamber; and a controller configured to control the processing chamber, the heater, the gas supply units, and the exhaust unit, wherein the controller controls a first gas supply unit to supply a first silane-based gas and a first etching gas in a first step, and the controller controls a second gas supply unit to supply a second silane-based gas and a second etching gas in a second step.

### BRIEF DESCRIPTION OF THE DRAWINGS

FIG. 1 illustrates a perspective view of a substrate processing apparatus according to an embodiment of the present invention.

FIG. 2 illustrates a schematic cross-sectional view of a substrate processing furnace and its surroundings according to an embodiment of the present invention.

FIG. 3 is a flowchart illustrating a method for forming an epitaxial film according to an embodiment 1 of the present invention.

FIG. 4 illustrates gas flow of the processing furnace according to an embodiment of the present invention.

FIG. 5 is a flowchart illustrating a method for forming an epitaxial film according to an embodiment 2 of the present invention.

FIG. 6 is a flowchart illustrating a method for forming an epitaxial film according to an embodiment 3 of the present invention.

FIG. 7 is a flowchart illustrating a method for forming an epitaxial film according to an embodiment 4 of the present invention.

### DETAILED DESCRIPTION OF THE PREFERRED EMBODIMENTS

A method for fabricating a semiconductor device will be described hereinafter in detail with reference to the attached drawings, in which exemplary embodiments of the invention are shown.

### Embodiment 1

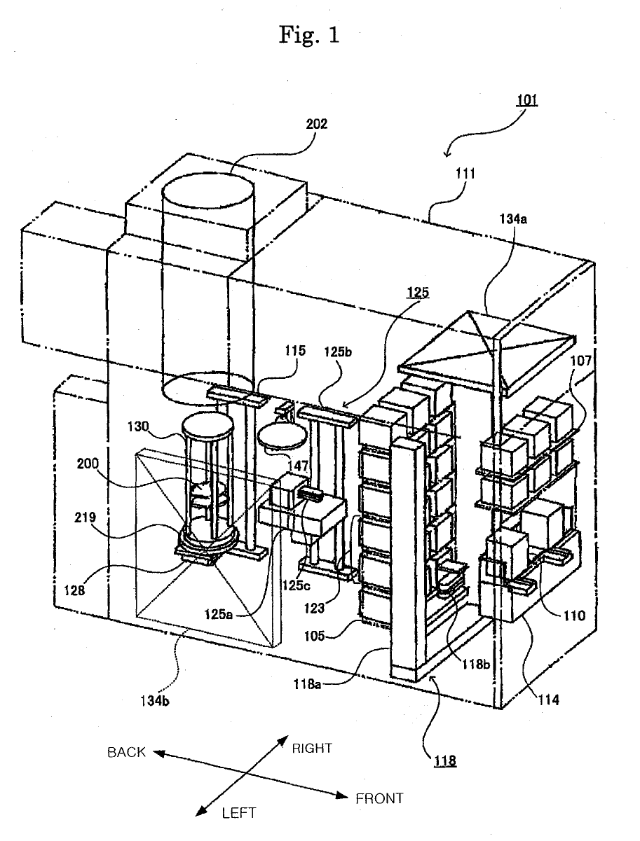

The current embodiment discusses a substrate processing apparatus as an example of a semiconductor device fabricating apparatus which performs a fabrication process for a method of fabricating a semiconductor device. FIG. 1 illustrates a perspective view of a substrate processing apparatus in accordance with the current embodiment of the present invention. The following description is made about a vertical type substrate processing apparatus which performs oxidation, diffusion, and/or chemical vapor deposition (CVD) process on a substrate. In addition, the following description is made with reference to the directions of arrows shown in FIG. 1.

As showing in FIG. 1, cassettes 110 are used to contain wafers 200 such as silicon wafers in a semiconductor device fabricating apparatus 101 which includes a housing 111.

The cassettes 110 are designed to be carried-in on a cassette stage 114 and carried-out from the cassette state 114 by an in-plant carrying unit (not shown). The carrying unit places the cassettes 110 on the cassette stage 114 with wafers 200 in the cassettes 110 being in an upright position and wafer carrying-in and carrying-out openings of the cassettes 110 facing upward. The cassette stage 114 is configured so that the cassette 110 is rotated 90 degrees counterclockwise in a longitudinal direction to the backward of the housing 111 in order to make the wafers 200 of the cassette 110 positioned horizontally and point the wafer carrying-in and carrying-out openings of the cassettes 110 toward the backward of the housing 111.

At nearly the center portion inside the housing 111 in a front-to-back direction, a cassette shelf 105 is installed to store a plurality of cassettes 110 in a plurality of steps and a plurality of rows. At the cassette shelf 105, a transfer shelf 123 is installed to store the cassettes 110. In addition, at the upward of the cassette stage 114, a standby cassette shelf 107 is installed to store a standby cassette 110.

Between the cassette stage 114 and the cassette shelf 105, a cassette carrying unit 118 is installed. The cassette carrying unit 118 is configured by a cassette elevator 118a, which is capable of holding and moving the cassette 110 upward and downward, and a cassette carrying mechanism 118b as a carrying mechanism. The cassette carrying unit 118 is designed to carry the cassette 110 in and out of the cassette stage 114, the cassette shelf 105, and/or the standby cassette shelf 118b by continuous motions of the cassette elevator 118a and the cassette transfer mechanism 118b.

At the rear of the cassette shelf 105, a wafer transfer mechanism 125 is installed. The wafer transfer mechanism 125 is configured by a wafer transfer unit 125a that is capable of rotating or linearly moving the wafer 200 in a horizontal direction, and an elevator 125b and tweezers 125c that is used to move the wafer transfer unit 125a upward and downward. The elevator 125b is installed in a right end portion of the housing 111. The elevator 125b and the wafer transfer unit 125a are successively operated for picking up a wafer 200 with the tweezers 125c of the wafer transfer unit 125a, and charging the wafer 200 to a boat 130 and discharging the wafer 200 from the boat 130.

A processing furnace 202 is installed in a rear upper portion of the housing 111. A furnace shutter 147 is used to open and close a lower end portion of the processing furnace 202. A boat elevator 115 is installed under the processing furnace 202 to move the boat 130 upward to the processing furnace 202 and downward from the processing furnace 202. A seal cap 219 is horizontally installed as a cover of an arm 128 which is connected to a base of the boat elevator 115. The seal cap 219 is configured to vertically support the boat 130 and close the lower end portion of the processing furnace 202. The lever 130 includes a plurality of holding members which hold a plurality of wafers 200 (for example, about fifty to one hundred wafers) in a horizontally oriented and vertically arranged format with the centers of the wafers 200 being vertically aligned.

A cleaning unit 134a is installed above the cassette shelf 105 for supplying filtered clean air to the inside of the housing 111. For this, the cleaning unit 134a includes a supply fan and a dust filter. Another cleaning unit 134b having a supply fan and a dust filter is installed in a left end portion of the housing 111 opposite to the boat elevator 115 and the elevator 125b of the wafer transfer mechanism 125 for supplying clean air. Clean air supplied from the cleaning unit 134b flows through the wafer transfer unit 125a and the boat 130 and is discharged from the housing 111 through an exhaust unit (not shown).

An exemplary operation of the substrate processing apparatus 101 will be described hereinafter in accordance with the current embodiment.

First, cassettes 110 are introduced through a cassette loading/unloading part (not shown), and the cassettes 110 are placed on the cassette stage 114 with wafers 200 of the cassettes 110 being in an upright position and the wafer carrying-in and carrying-out openings of the cassettes 110 facing upward. Then, by the cassette stage 114, the cassettes 110 are rotated 90 degrees counterclockwise in a longitudinal direction to the backward of the housing 111 so that the wafers 200 of the cassettes 110 are positioned horizontally and the wafer carrying-in and carrying-out openings of the cassettes 110 pointing toward the backward of the housing 111.

Thereafter, the cassettes 110 are automatically carried to destined positions of the cassette shelf 105 or the standby cassette shelf 107 by the cassette carrying unit 118 and are temporarily stored. Then, the cassettes 110 are transferred from the cassette shelf 105 or the standby cassette shelf 107 to the transfer shelf 123 directly or by the cassette carrying unit 118.

After the cassettes 110 are transferred to the transfer shelf 123, the tweezers 125c and the wafer transfer unit 125a pick up a wafer 200 from the cassette 110 through the wafer opening of the cassette 110 and load the wafer 200 into the boat 130. Then, the wafer transfer unit 125a is moved back to the cassette 110 for charging another wafer 200 into the boat 130.

After a predetermined number of wafers 200 are loaded in the boat 130, the lower end portion of the processing furnace 202 is opened by the furnace shutter 147. Thereafter, the boat elevator 115 lifts the seal cap 219 to load the boat 130 charged with the wafers 200 into the processing furnace 202.

After the boat 130 is loaded, the wafers 200 are processed in the processing furnace 202. Then, the wafers 200 and the cassettes 110 are unloaded from the housing 111 in a reverse order.

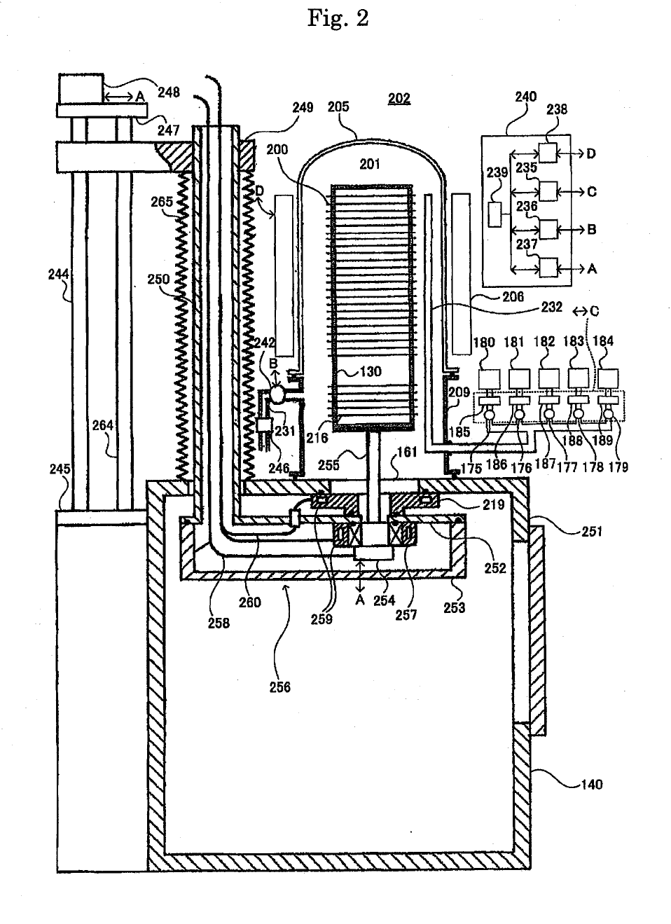

An exemplary structure of the processing furnace 202 will be described hereinafter. FIG. 2 illustrates a schematic cross-sectional view of the processing furnace 202 and its surroundings according to an embodiment of the present invention.

As shown in FIG. 2, the processing furnace 202 includes a heater 206. The heater 206 is cylinder-shaped and includes a heating wire and an insulating material around the heating wire. The heater 206 is vertically supported by a holder (not shown).

An outer tube 205 is coaxially installed inside the heater 206 as a reaction tube. The outer tube 205 is made of a heat-resistant material such as quartz (SiO₂) or silicon carbide (SiC). The outer tube 205 has a hollow cylindrical shape with a closed upper end and an opened lower end. In the hollow cylindrical part of the outer tube 205, a processing chamber 201 is formed to accommodate the boat 130 in which substrates such as wafers 200 are horizontally oriented and vertically arranged in multiple stages.

A manifold 209 is coaxially installed under the outer tube 205. For example, the manifold 209 may be made of stainless steel and have a cylindrical shape with opened upper and lower ends. The manifold 209 is installed to support the outer tube 205. An O-ring is disposed therebetween the outer tube 205 and the manifold 209 as a seal. The manifold 209 is supported by a holder (not shown) so that the outer tube 205 is kept in an upright position. A reaction chamber is formed by the outer tube 205 and the manifold 209.

A gas exhaust pipe 231 is installed at the manifold 209, and a gas supply pipe 232 is installed through the manifold 209 as well. The gas supply pipe 232 is divided into five branches at an upstream side which The five branches are connected to a first gas supply source 180, a second gas supply source 181, a third gas supply source 182, a fourth gas supply source 183, and a fifth gas supply source 184 respectively. Valves 175 to 179, and mass flow controllers (MFCs) 185 to 189 that are used to control gas flow are disposed between the five branches and the first to fifth gas supply sources 180 to 184. A gas flow controller 235 is electrically connected to the MFCs 185 to 189 and the valves 175 to 179 so as to supply desired amounts of gas at desired time. A vacuum exhaust unit 246 such as a vacuum pump is connected to a downstream side of the gas exhaust pipe 231 through a pressure sensor (not shown) as a pressure detector and an automatic pressure controller (APC) valve 242 as a pressure regulator. The pressure sensor and the APC valve 242 are electrically connected to a pressure controller 236 so that the pressure controller 236 can control the APC valve 242 based on a pressure detected by the pressure sensor to adjust the pressure in the processing chamber 201 to a desired level at a desired time.

The seal cap 219 is installed under the manifold 209 as a furnace cover for sealing the opened lower end of the manifold 209. For example, the seal cap 219 may be made of stainless steel and have a disk shape. An O-ring is disposed on the top of the seal cap 219 as a seal. The O-ring is in contact with the lower end of the manifold 209. A rotating mechanism 254 is installed at the seal cap 219. A rotation shaft 255 of the rotating mechanism 254 is connected to the boat 130 through the seal cap 219 to rotate the boat 130 (described later in detail) to rotate wafers 200 charged inside the boat 130. The seal cap 219 is moved vertically by a lift mechanism actuated by a lift motor 248 (described later in detail) installed outside the processing furnace 202 so that the boat 130 can be loaded into and unloaded from the processing chamber 201. A driving controller 237 is electrically connected to the rotating mechanism 254 and the lift motor 248 to control a predetermined operation at a desired time.

The boat 130 used as a holder is made of heat resistant material such as quartz or silicon carbide and is configured to hold a plurality of horizontally oriented wafers 200 in multiple stages with centers of the wafers 200 being aligned with each other. At a lower portion of the boat 130, a plurality of heat resistant members, such as circular heat resistant plates 216 made of a heat resistant material such as quartz or silicon carbide, are horizontally oriented in multiple stages to prevent heat, transfer from the heater 206 to the manifold 209.

A temperature detector such as a temperature sensor (not shown) is installed at a position adjacent to the heater 206 to measure the temperature inside the processing chamber 201. The heater 206 and the temperature sensor are electrically connected to a temperature controller 238 so that the temperature of the processing chamber 201 can be maintained at a desired temperature distribution at desired time by controlling the power condition of the heater 206 based on temperature information detected from the temperature sensor.

In this configuration of the processing furnace 202, a first processing gas is supplied from the first gas supply source 180, and the flow rate of the first processing gas is controlled by the MFC 185. Then, the first processing gas is introduced into the processing chamber 201 by the gas supply pipe 232 through the valve 175. A second processing gas is supplied from the second gas supply source 181, and the flow rate of the second processing gas is controlled by the MFC 186. Then, the second processing gas is introduced into the processing chamber 201 by the gas supply pipe 232 through the valve 176. A third processing gas is supplied from the third gas supply source 182, and the flow rate of the third processing gas is controlled by the MFC 187. Then, the third processing gas is introduced into the processing chamber 201 by the gas supply pipe 232 through the valve 177. A fourth processing gas is supplied from the fourth gas supply source 183, and the flow rate of the fourth processing gas is controlled by the MFC 188. Then, the fourth processing gas is introduced into the processing chamber 201 by the gas supply pipe 232 through the valve 178. A fifth processing gas is supplied from the fifth gas supply source 184, and the flow rate of the fifth processing gas is controlled by the MFC 189. Then, the fifth processing gas is introduced into the processing chamber 201 by the gas supply pipe 232 through the valve 179. The processing gas is discharged from the processing chamber 201 by an exhaust unit such as the vacuum pump 246 connected to the gas exhaust pipe 231.

An exemplary surrounding structure of the processing furnace of the substrate processing apparatus 101 will now be described.

As shown in FIG. 2, a lower base 245 is installed on an outer side of an auxiliary chamber such as a loadlock chamber 140. On the lower base 245, a guide shaft 264 inserted in a lift plate 249 and a ball screw 244 coupled to the lift plate 249 are installed. The guide shaft 264 and the ball screw 244 are erected on the lower base 245, and an upper base 247 is installed on the upper ends of the guide shaft 264 and the ball screw 244. The ball screw 244 is rotated by the lift motor 248 installed on the upper base 247. The lift plate 249 is moved upward or downward by rotating the ball screw 244.

On the lift plate 249, a hollow lift shaft 250 is erected, and a connected area between the lift plate 249 and the lift shaft 250 is sealed. The lift shaft 250 is configured to be moved upward and downward together with the lift plate 249. The lift shaft 250 is loosely inserted through a top plate 251 of the loadlock chamber 140. A penetration hole of the top plate 251 through which the lift shaft 250 is inserted is large enough for preventing the lift shaft 250 from contacting the top plate 251. Between the loadlock chamber 140 and the lift plate 249, a flexible hollow structure such as a bellows 265 is installed to enclose the lift shaft 250 for sealing the loadlock chamber 140. The bellows 265 is sufficiently expanded and contracted in accordance with a movement of the lift plate 249 and has an inner diameter sufficiently larger than the outer diameter of the lift shaft 250 for preventing contacting with the lift shaft 250 upon expansion or contraction.

A lift base 252 is horizontally fixed to a lower end of the lift shaft 250. A driver cover 253 is hermetically coupled to the bottom of the lift base 252 with a seal such as an O-ring being interposed therebetween. The lift base 252 and the driver cover 253 form a driver case 256. Therefore, the inside of the driver case 256 is isolated from the inside atmosphere of the loadlock chamber 140.

The rotating mechanism 254 for the boat 130 is installed inside the driver case 256 for rotating the boat 130, and the surrounding of the rotating mechanism 254 is cooled by a cooling mechanism 257.

Power cables 258 are connected from an upper end of the hollow lift shaft 250 to the rotating mechanism 254 through the hollow lift shaft 250. Cooling passages 259 are formed in the cooling mechanism 257 and the seal cap 219, and a coolant tube 260 is connected from the upper end of the hollow lift shaft 250 to the cooling passages 259 through the hollow lift shaft 250 for supplying cooling water.

As the ball screw 244 rotates upon the driving of the lift motor 249, the driver case 256 is lifted together with the lift plate 249 and the lift shaft 250.

As the driver case 256 is lifted, the seal cap 219 to which the lift base 252 is hermetically installed can close a furnace opening 161 of the processing furnace 202, and thus wafer processing can be started. As the driver accommodation case 256 is moved down, the seal cap 219 and the boat 130 are also moved down, and thus the wafers 200 are ready to be unloaded to the outside.

The gas flow controller 235, the pressure controller 236, the driving controller 237, and the temperature controller 238 constitute an operation control unit and an input/output unit, which are electrically connected to a main controller 239 which controls the overall operation of the substrate processing apparatus 101. The gas flow controller 235, the pressure controller 236, the driving controller 237, the temperature controller 238, and the main controller 239 constitute a controller 240, as a whole.

In the current embodiment, a wafer 200 includes a silicon surface and an insulation film such as an oxide film.

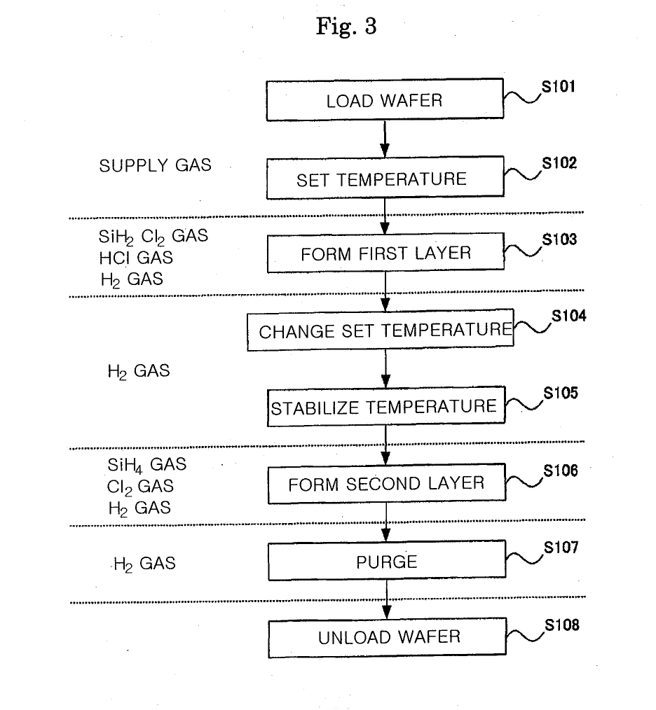

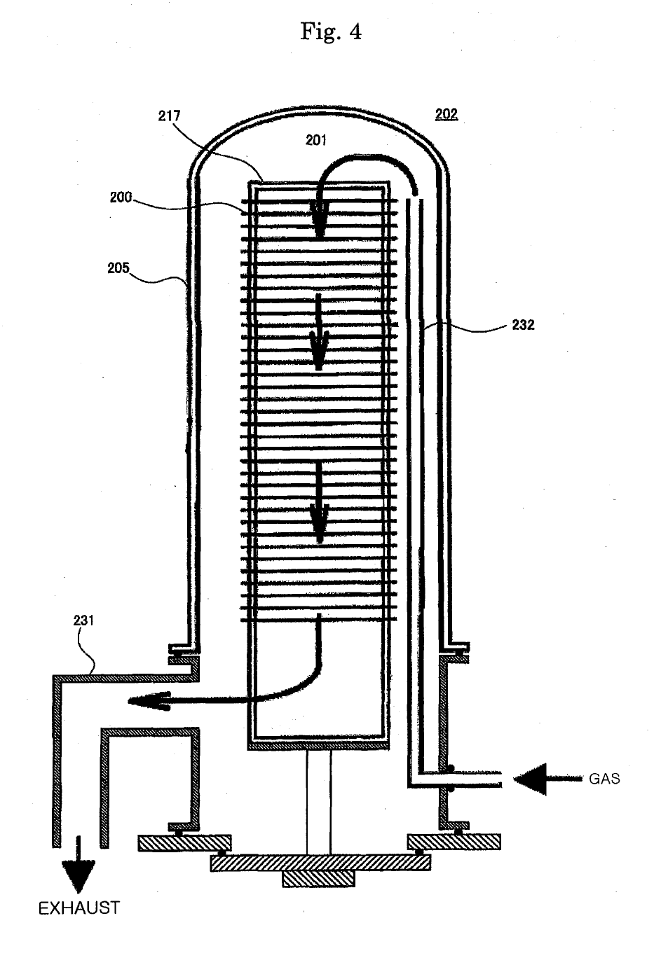

Hereinafter, as a process for fabricating a semiconductor device using the processing furnace, a method for selectively growing a silicon epitaxial film only on a single-crystal silicon surface of a wafer will be described hereinafter with reference to FIG. 2, FIG. 3, and FIG. 4. FIG. 3 is a flowchart for explaining a method for forming an epitaxial film in accordance with the current embodiment, and FIG. 4 illustrates gas flow of the processing furnace. In the following description, operations of the elements of the substrate processing apparatus are controlled by a controller (controlling means). In addition, a film is formed on a silicon surface by growing a first film to a thickness of 10 Å to 2000 Å, and a second film to a thickness of the remainder of the film.

First, a plurality of wafers 200 (silicon substrates) are charged to the boat 130, and the lift motor 248 is operated to move up the lift plate 249 and the lift shaft 250 so as to load the boat 130 into the processing chamber 201 (S101, first step). In this state, the lower end of the manifold 209 is sealed by the seal cap 219 with an O-ring being interposed therebetween.

Next, the inside of processing chamber 201 is exhausted by the vacuum exhaust unit 246 to form a vacuum at a desired pressure (vacuum degree). At this time, the pressure inside the processing chamber 201 is measured with a pressure sensor, and the pressure regulator 242 is feedback controlled based on the measured pressure. The inside of the processing chamber 201 is heated (S102, second step) by the heater 206 (heating means) to a desired temperature (a first temperature) suitable for forming a first film. When the heater 206 heats the processing chamber 201, power to the heater 206 is feedback controlled based on temperature information detected by a temperature sensor so as to obtain a desired temperature distribution throughout the processing chamber 201. Thereafter, the rotating mechanism 254 rotates the boat 130 in which the wafers 200 are charged.

A plurality of gas supply units, for example, the first gas supply source 180, the second gas supply source 181, the third gas supply source 182, the fourth gas supply source 183, and the fifth gas supply source 184 are used to store SiH₂Cl₂, HCl, H₂, SiH₄, and Cl₂ gases, respectively. The first gas supply source 180 supplies the SiH₂Cl₂ gas (a first silane-based gas) as a film-forming gas. The second gas supply source 181 supplies the HCl gas as an etching gas (a first etching gas). The third gas supply source 182 supplies the H₂ gas as a dilution gas for the SiH₂Cl₂ gas. To control desired gas flow, openings of the MFCs 185 to 187 are adjusted, and the valves 175 to 177 are opened to introduce the processing gases to an upper portion of the processing chamber 201 through the gas supply pipe 232. Referring to FIG. 4, the introduced gases are discharged from the processing chamber 201 through the gas exhaust pipe 231 (an exhaust unit). While the SiH₂Cl₂ gas passes through the processing chamber 201, the SiH₂Cl₂ gas makes contacts with the wafers 200 to form films on surfaces of the wafers 200. The HCl gas etches the films formed on silicon oxide films of the wafers 200 by the SiH₂Cl₂ gas. As a result, high-temperature silicon selective epitaxial films can be formed on the wafers 200 as first films (S103, second step).

After a predetermined time passed, the valves 175 and 176 of the first and second gas supply sources 180 and 181 are respectively closed to cut off supplies of the SiH₂Cl₂ and HCl gases, and while the H₂ gas being supplied to the processing chamber 201, power condition to the heater 206 is feedback controlled so that the temperature (a second temperature) of the processing chamber 201 can be suitable for forming second films (S104, third step). Here, the reason for supplying the H₂ gas to the processing chamber 201 is to prevent reverse diffusion of impurities such as oxygen or carbon to the high-temperature silicon selective epitaxial films formed in the second step as the first films. By supplying the H₂ gas, Cl end groups of the high-temperature silicon selective epitaxial films formed in the second step as the first films can be terminated by hydrogen, and thus, the high-temperature silicon selective epitaxial films can have better quality.

As a result that the temperature distribution of the processing chamber 201 reaches a desired level and becomes stable (S105), and while the H₂ gas being supplied, the fourth gas supply source 183 supplies the SiH₄ gas (a second silane-based gas) as a film-forming gas, and the fifth gas supply source 184 supplies the Cl₂ gas as an etching gas (a second etching gas). To control desired gas flow, openings of the MFCs 188 and 189 are adjusted, and the valves 178 and 179 are opened to supply the SiH₄ and Cl₂ gases to the upper portion of the processing chamber 201 through the gas supply pipe 232. While the SiH₄ gas passes through the processing chamber 201, the SiH₄ gas makes contact with the wafers 200 to form films on the surfaces of the wafers 200. The Cl₂ gas etches the films formed on the silicon oxide films of the wafers 200 by the SiH₄ gas. As a result, low-temperature silicon selective epitaxial films can be formed as second films (S106, fourth step).

After a predetermined time interval, the valves 178 and 179 of the fourth and fifth gas supply sources 183 and 184 are closed to cut off supplies of the SiH₄ and Cl₂ gases. Then, the inside of the processing chamber 201 is replaced with H₂ or N₂ gas, and the pressure of the processing chamber 201 returns to atmospheric pressure (S107).

Thereafter, the lift motor 248 is operated to move down the seal cap 219 and open the lower end of the manifold 209, and the processed wafers 200 charged in the boat 130 are unloaded from the lower end of the manifold 209 to the outside of the outer tube 205. Then, the wafers 200 are discharged from the boat 130 (S108).

In the current embodiment, the processing conditions of wafers 200 in the processing furnace 202 are as follows. For example, high-temperature silicon selective epitaxial films (first films) are formed at a temperature of 700° C. to 850° C., a SiH₂Cl₂ gas flow of 1 sccm to 1000 sccm, a HCl gas flow of 1 sccm to 1000 sccm, a H₂ gas flow of 10 sccm to 50000 sccm, and a processing pressure equal to or lower than 2000 pa. In changing from a first film forming temperature to a second film forming temperature, for example, H₂ gas flow of 10 sccm to 50000 sccm, and a processing pressure equal to or lower than 2000 pa are given. For example, low-temperature silicon selective epitaxial films (second films) are formed at a temperature of 500° C. to 750° C., a SiH₄ gas flow of 1 sccm to 1000 sccm, a Cl₂ gas flow of 1 sccm to 1000 sccm, a H₂ gas flow of 10 sccm to 50000 sccm, and a processing pressure equal to or lower than 2000 pa. The processing conditions may be kept constant in each operation within the above-mentioned exemplary ranges.

As described above, HCl gas is used as a first film etching gas since an N⁺ substrate is not affected by HCl gas, and after a first film is formed, SiH₄ gas is used as a second film forming gas since SiH₄ gas allows low film forming temperature, less thermal damage to a wafer 200, and a high film forming rate. Therefore, films can be rapidly formed on the wafers 200 without affecting the N⁺ areas of the wafers 200.

### Embodiment 2

In the embodiment 1, supplies of SiH₂Cl₂ gas and HCl gas to the processing chamber 201 are cut off but supply of H₂ gas to the processing chamber 201 is continued after the first films are formed. However, in this case, moisture generated from the oxide films of the wafers 200 can attach to the silicon selective epitaxial films (the first films) formed on the wafers 200, and thus surface oxygen content of the first films can undesirably increase.

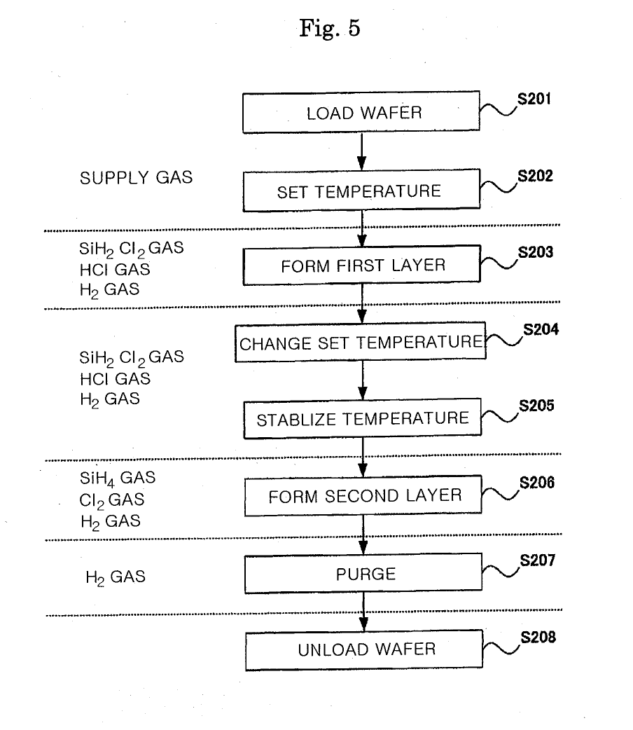

Therefore, in the current embodiment, supplies of SiH₂Cl₂ gas and HCl gas as well as supply of H₂ gas are not cut off after first films are formed. Supplies of SiH₂Cl₂ gas and HCl gas are continued until the temperature of the processing chamber 201 becomes stable for forming second films. Hereinafter, a method of forming an epitaxial film will be described with reference to a flowchart of FIG. 5 in accordance with the current embodiment. In the current embodiment, the epitaxial film forming method is performed using the same processing apparatus as that used in the embodiment 1.

First, a plurality of wafers 200 (silicon substrates) are charged in the boat 130, and then the lift motor 248 is operated to move up the lift plate 249 and the lift shaft 250 so as to load the boat 130 into the processing chamber 201 (S201, first step). In this state, the lower end of the manifold 209 is sealed by the seal cap 219 with an O-ring being disposed therebetween.

Next, the inside of processing chamber 201 is exhausted by the vacuum exhaust unit 246 to form a vacuum at a desired pressure (vacuum degree). At this time, the pressure inside the processing chamber 201 is measured with a pressure sensor, and the pressure regulator 242 is feedback controlled based on the measured pressure. The inside of the processing chamber 201 is heated (S202, second step) by the heater 206 (heating means) to a desired temperature (a first temperature) suitable for forming a first film. When the heater 206 heats the processing chamber 201, power to the heater 206 is feedback controlled based on temperature information detected by a temperature sensor so as to obtain a desired temperature distribution throughout the processing chamber 201. Thereafter, the rotating mechanism 254 rotates the boat 130 in which the wafers 200 are charged.

Next, a plurality of gas supply units, for example, the first gas supply source 180, the second gas supply source 181, the third gas supply source 182, the fourth gas supply source 183, and the fifth gas supply source 184 are used to store SiH₂Cl₂, HCl, H₂, SiH₄, and Cl₂ gases, respectively. The first gas supply source 180 supplies the SiH₂Cl₂ gas (a first silane-based gas) as a film-forming gas. The second gas supply source 181 supplies the HCl gas as an etching gas (a first etching gas). The third gas supply source 182 supplies the H₂ gas as a dilution gas for the SiH₂Cl₂ gas. To control desired gas flow, openings of the MFCs 185 to 187 are adjusted, and the valves 175 to 177 are opened to introduce the processing gases to an upper portion of the processing chamber 201 through the gas supply pipe 232. Referring to FIG. 4, the introduced gases are discharged from the processing chamber 201 through the gas exhaust pipe 231 (an exhaust unit). While the SiH₂Cl₂ gas passes through the processing chamber 201, the SiH₂Cl₂ gas makes contacts with the wafers 200 to form films on surfaces of the wafers 200. The HCl gas etches the films formed on silicon oxide films of the wafers 200 by the SiH₂Cl₂ gas. As a result, high-temperature silicon selective epitaxial films can be formed on the wafers 200 as first films (S203, second step).

Even after a predetermined time interval set for forming the first films, supplies of the SiH₂Cl₂, HCl, and H₂ gases are continued. In this state, power condition to the heater 206 is feedback controlled so that the temperature (a second temperature) of the processing chamber 201 can be suitable for forming second films (S204, third step).

As a result that the temperature distribution of the processing chamber 201 reaches a desired level and becomes stable (S205), the valves 175 and 176 of the first and second gas supply sources 180 and 181 are closed to cut off supplies of the SiH₂Cl₂ and HCl gases. Thereafter, the fourth gas supply source 183 supplies the SiH₄ gas (a second silane-based gas) as a film-forming gas, and the fifth gas supply source 184 supplies the Cl₂ gas as an etching gas (a second etching gas). To control desired gas flow, the openings of the MFCs 188 and 189 are adjusted, and the valves 178 and 179 are opened to supply the SiH₄ and Cl₂ gases to the upper portion of the processing chamber 201 through the gas supply pipe 232. While the SiH₄ gas passes through the processing chamber 201, the SiH₄ gas makes contact with the wafers 200 to form films on the surfaces of the wafers 200. The Cl₂ gas etches the films formed on the silicon oxide films of the wafers 200 by the SiH₄ gas. As a result, low-temperature silicon selective epitaxial films can be formed as second films (S206, fourth step).

After a predetermined time interval, the valves 178 and 179 of the fourth and fifth gas supply sources 183 and 184 are closed to cut off supplies of the SiH₄ and Cl₂ gases. Then, the inside of processing chamber 201 is replaced with the H₂ gas, and the pressure of the processing chamber 201 returns to atmospheric pressure (S207).

Thereafter, the lift motor 248 is operated to move down the seal cap 219 and open the lower end of the manifold 209, and the processed wafers 200 charged in the boat 130 are unloaded from the lower end of the manifold 209 to the outside of the outer tube 205. Then, the wafers 200 are discharged from the boat 130 (S208).

In the current embodiment, the processing conditions of wafers 200 in the processing furnace 202 are as follows. For example, high-temperature silicon selective epitaxial films (first films) are formed at a temperature of 700° C. to 850° C., a SiH₂Cl₂ gas flow of 1 sccm to 1000 sccm, a HCl gas flow of 1 sccm to 1000 sccm, a H₂ gas flow of 10 sccm to 50000 sccm, and a processing pressure equal to or lower than 2000 pa. In changing from a first film forming temperature to a second film forming temperature, for example, SiH₂Cl₂ gas flow of 1 sccm to 1000 sccm, HCl gas flow of 1 sccm to 1000 sccm; H₂ gas flow of 10 sccm to 50000 sccm; and a processing pressure equal to or lower than 2000 pa are given. For example, low-temperature silicon selective epitaxial films (second films) are formed at a temperature of 500° C. to 750° C., a SiH₄ gas flow of 1 sccm to 1000 sccm, a Cl₂ gas flow of 1 sccm to 1000 sccm, a H₂ gas flow of 10 sccm to 50000 sccm, and a processing pressure equal to or lower than 2000 pa. The processing conditions may be kept constant in each operation within the above-mentioned exemplary ranges.

As explained above, supplies of SiH₂Cl₂ gas and HCl gas are continued after the first films are formed. H₂ gas does not function as a reduction gas unless temperature is high at about 800° C.; however, SiH₂Cl₂ gas functions as a reduction gas at a temperature lower than 800° C. Therefore, while lowering temperature after formation of the first films, impurities such as moisture can be removed from silicon surfaces by the SiH₂Cl₂ gas. In addition, by the HCl gas functioning as an etching gas, selectivity can be maintained.

Although it varies from wafer to wafer, inspection results using a surface secondary ionization mass spectrometer (SIMS) are as follows. In the case where only H₂ gas is supplied during transition from a first film forming temperature to a second film forming temperature, a peak value of surface oxygen content is 2E19 atoms/cm³ or more; however, in the case where SiH₂Cl₂ and HCl gas as well as H₂ gas are supplied, a peak value of surface oxygen content is relatively low at 1E19 atoms/cm³ or lower.

### Embodiment 3

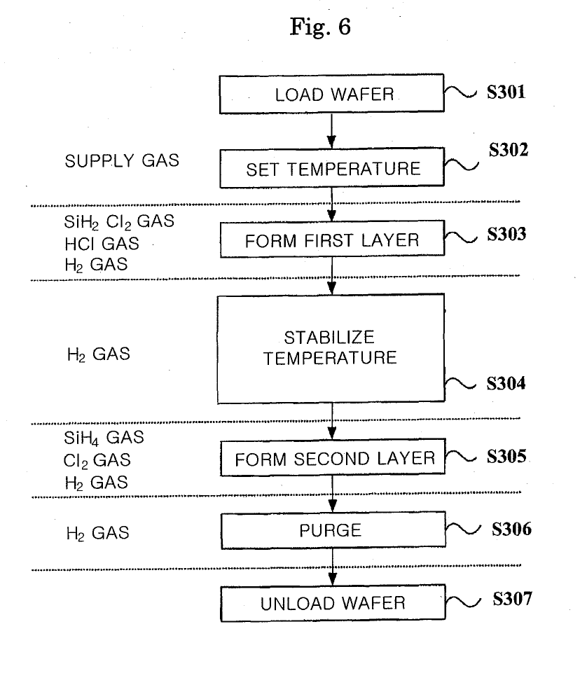

In the embodiment 3, first and second films are formed at the same constant temperature for continuous processing. Hereinafter, a method of forming an epitaxial film will be described with reference to a flowchart of FIG. 6 in accordance with the current embodiment. In the current embodiment, the epitaxial film forming method is performed using the same processing apparatus as that used in the embodiment 1.

First, a plurality of wafers 200 (silicon substrates) are charged to the boat 130, and then the lift motor 248 is operated to move up the lift plate 249 and the lift shaft 250 so as to load the boat 130 into the processing chamber 201 (S301, first step). In this state, the lower end of the manifold 209 is sealed by the seal cap 219 with an O-ring being disposed therebetween.

Next, the inside of processing chamber 201 is exhausted by the vacuum exhaust unit 246 to form a vacuum at a desired pressure (vacuum degree). At this time, the pressure inside the processing chamber 201 is measured with a pressure sensor, and the pressure regulator 242 is feedback controlled based on the measured pressure. The inside of the processing chamber 201 is heated (S302, second step) by the heater 206 (heating means) to a desired temperature (a first temperature) suitable for forming a first film. When the heater 206 heats the processing chamber 201, power to the heater 206 is feedback controlled based on temperature information detected by a temperature sensor so as to obtain a desired temperature distribution throughout the processing chamber 201. Thereafter, the rotating mechanism 254 rotates the boat 130 in which the wafers 200 are charged.

A plurality of gas supply units, for example, the first gas supply source 180, the second gas supply source 181, the third gas supply source 182, the fourth gas supply source 183, and the fifth gas supply source 184 are used to store SiH₂Cl₂, HCl, H₂, SiH₄, and Cl₂ gases, respectively. The first gas supply source 180 supplies the SiH₂Cl₂ gas (a first silane-based gas) as a film-forming gas. The second gas supply source 181 supplies the HCl gas as an etching gas (a first etching gas). The third gas supply source 182 supplies the H₂ gas as a dilution gas for the SiH₂Cl₂ gas. To control desired gas flow, openings of the MFCs 185 to 187 are adjusted, and the valves 175 to 177 are opened to introduce the processing gases to an upper portion of the processing chamber 201 through the gas supply pipe 232. Referring to FIG. 4, the introduced gases are discharged from the processing chamber 201 through the gas exhaust pipe 231 (an exhaust unit). While the SiH₂Cl₂ gas passes through the processing chamber 201, the SiH₂Cl₂ gas makes contacts with the wafers 200 to form films on surfaces of the wafers 200. The HCl gas etches the films formed on silicon oxide films of the wafers 200 by the SiH₂Cl₂ gas. As a result, high-temperature silicon selective epitaxial films can be formed on the wafers 200 as first films (S303, second step).

After a predetermined time passed, the valves 175 and 176 of the first and second gas supply sources 180 and 181 are respectively closed to cut off supplies of the SiH₂Cl₂ and HCl gases, and only the H₂ gas is supplied without changing the temperature of the processing chamber 201 (S304). Here, the reason for supplying the H₂ gas to the processing chamber 201 is to prevent reverse diffusion of impurities such as oxygen or carbon to the high-temperature silicon selective epitaxial films formed in the second step as first films. By supplying the H₂ gas, Cl end groups of the high-temperature silicon selective epitaxial films formed in the second step as first film can be terminated by hydrogen, and thus the high-temperature silicon selective epitaxial films can have better quality.

After the H₂ gas is supplied to the processing chamber 201 for a predetermined time at a stable temperature state, while the supply of the H₂ gas being continued, the fourth gas supply source 183 supplies a SiH₄ gas (a second silane-based gas) as a film-forming gas, and the fifth gas supply source 184 supplies a Cl₂ gas as an etching gas (a second etching gas). To control desired gas flow, the openings of the MFCs 188 and 189 are adjusted, and the valves 178 and 179 are opened to supply the SiH₄ and Cl₂ gases to the upper portion of the processing chamber 201 through the gas supply pipe 232. While the SiH₄ gas passes through the processing chamber 201, the SiH₄ gas makes contact with the wafers 200 to form films on the surfaces of the wafers 200. The Cl₂ gas etches the films formed on the silicon oxide films of the wafers 200 by the SiH₄ gas. As a result, low-temperature silicon selective epitaxial films can be formed as second films (S305, third step).

After a predetermined time interval, the valves 178 and 179 of the fourth and fifth gas supply sources 183 and 184 are closed to cut off supplies of the SiH₄ and Cl₂ gases. Then, the inside of the processing chamber 201 is replaced with H₂ gas, and the pressure of the processing chamber 201 returns to atmospheric pressure (S306).

Thereafter, the lift motor 248 is operated to move down the seal cap 219 and open the lower end of the manifold 209, and the processed wafers 200 charged in the boat 130 are unloaded from the lower end of the manifold 209 to the outside of the outer tube 205. Then, the wafers 200 are discharged from the boat 130 (S307).

In the current embodiment, the processing conditions of wafers 200 in the processing furnace 202 are as follows. For example, high-temperature silicon selective epitaxial films (first films) are formed at a temperature of 500° C. to 850° C., a SiH₂Cl₂ gas flow of 1 sccm to 1000 sccm, a HCl gas flow of 1 sccm to 1000 sccm, a H₂ gas flow of 10 sccm to 50000 sccm, and a processing pressure equal to or lower than 2000 pa. In changing from a first film forming temperature to a second film forming temperature, for example, a H₂ gas flow of 10 sccm to 50000 sccm, and a processing pressure equal to or lower than 2000 pa are given. For example, low-temperature silicon selective epitaxial films (second films) are formed at a temperature of 500° C. to 850° C., a SiH₄ gas flow of 1 sccm to 1000 sccm, a Cl₂ gas flow of 1 sccm to 1000 sccm, a H₂ gas flow of 10 sccm to 50000 sccm, and a processing pressure equal to or lower than 2000 pa. The processing conditions may be kept constant in each operation within the above-mentioned exemplary ranges. In the current embodiment, the first and second films are formed at a constant temperature of 500° C. to 850° C. Preferably, the first and second films may be formed at a temperature of about 700° C.

As described above, the first and second films are formed at a constant temperature for continuously forming two kinds of films. Therefore, film forming time can be reduced, and processing efficiency can be increased.

### Embodiment 4

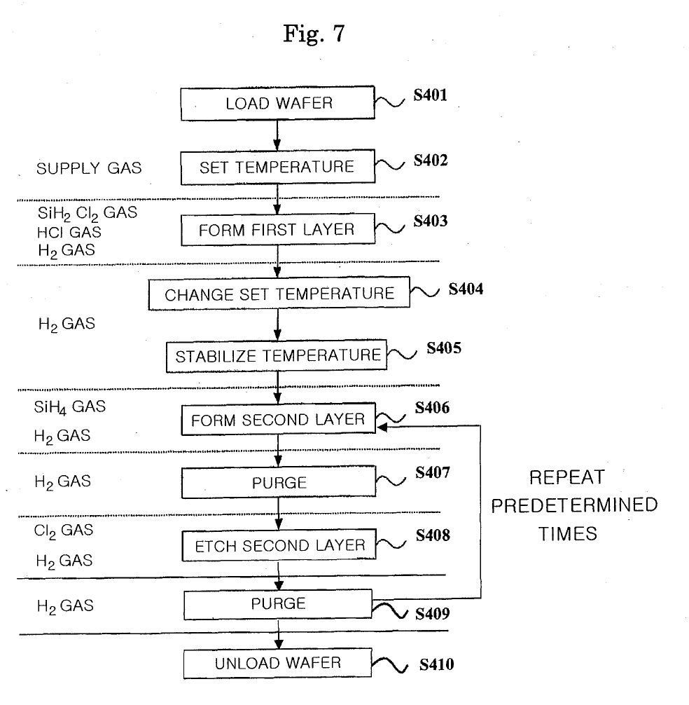

According to the embodiment 4, in a step of forming a second film, second silane-based gas and second etching gas are not simultaneously supplied but are alternately supplied a plurality of times. Hereinafter, a method of forming an epitaxial film will be described with reference to a flowchart of FIG. 7 in accordance with the current embodiment. In the current embodiment, the epitaxial film forming method is performed using the same processing apparatus as that used in the embodiment 1.

A plurality of wafers 200 (silicon substrates) are charged to the boat 130, and then the lift motor 248 is operated to move up the lift plate 249 and the lift shaft 250 so as to load the boat 130 into the processing chamber 201 (S401, first step). In this state, the lower end of the manifold 209 is sealed by the seal cap 219 with an O-ring being disposed therebetween.

Next, the inside of processing chamber 201 is exhausted by the vacuum exhaust unit 246 to form a vacuum at a desired pressure (vacuum degree). At this time, the pressure inside the processing chamber 201 is measured with a pressure sensor, and the pressure regulator 242 is feedback controlled based on the measured pressure. The inside of the processing chamber 201 is heated (S402, second step) by the heater 206 (heating means) to a desired temperature (a first temperature) suitable for forming a first film. When the heater 206 heats the processing chamber 201, power to the heater 206 is feedback controlled based on temperature information detected by a temperature sensor so as to obtain a desired temperature distribution throughout the processing chamber 201. Thereafter, the rotating mechanism 254 rotates the boat 130 in which the wafers 200 are charged.

Next, a plurality of gas supply units, for example, the first gas supply source 180, the second gas supply source 181, the third gas supply source 182, the fourth gas supply source 183, and the fifth gas supply source 184 are used to store SiH₂Cl₂, HCl, H₂, SiH₄, and Cl₂ gases, respectively. The first gas supply source 180 supplies the SiH₂Cl₂ gas (a first silane-based gas) as a film-forming gas. The second gas supply source 181 supplies the HCl gas as an etching gas (a first etching gas). The third gas supply source 182 supplies the H₂ gas as a dilution gas for the SiH₂Cl₂ gas. To control desired gas flow, openings of the MFCs 185 to 187 are adjusted, and the valves 175 to 177 are opened to introduce the processing gases to an upper portion of the processing chamber 201 through the gas supply pipe 232. Referring to FIG. 4, the introduced gases are discharged from the processing chamber 201 through the gas exhaust pipe 231 (an exhaust unit). While the SiH₂Cl₂ gas passes through the processing chamber 201, the SiH₂Cl₂ gas makes contacts with the wafers 200 to form films on surfaces of the wafers 200. The HCl gas etches the films formed on silicon oxide films of the wafers 200 by the SiH₂Cl₂ gas. As a result, high-temperature silicon selective epitaxial films can be formed on the wafers 200 as first films (S403, second step).

After a predetermined time passed, the valves 175 and 176 of the first and second gas supply sources 180 and 181 are respectively closed to cut off supplies of the SiH₂Cl₂ and HCl gases, and while the H₂ gas being supplied to the processing chamber 201, power condition to the heater 206 is feedback controlled so that the temperature (a second temperature) of the processing chamber 201 can be suitable for forming second films (S404, third step). Here, the reason for supplying the H₂ gas to the processing chamber 201 is to prevent reverse diffusion of impurities such as oxygen or carbon to the high-temperature silicon selective epitaxial films formed in the second step as the first films. By supplying the H₂ gas, Cl end groups of the high-temperature silicon selective epitaxial films formed in the second step as the first films can be terminated by hydrogen, and thus, the high-temperature silicon selective epitaxial films can have better quality.

As a result that the temperature distribution of the processing chamber 201 reaches a desired level and becomes stable (S405), and while the H₂ gas being supplied, the fourth gas supply source 183 supplies the SiH₄ gas (a second silane-based gas) as a film-forming gas. To control desired gas flow, the opening of the MFC 188 is adjusted, and then the valve 178 is opened to supply the SiH₄ gas to the upper portion of the processing chamber 201 through the gas supply pipe 232. While the SiH₄ gas passes through the processing chamber 201, the SiH₄ gas makes contact with the wafers 200 to form films on the wafers 200. As a result, low-temperature silicon selective epitaxial films can be formed as second films (S406, fourth step).

After a predetermined time interval, the valve 178 of the fourth gas supply source 183 is closed to cut off the SiH₄ gas. Then, the inside of the processing chamber 201 is replaced with H₂ gas (S407, fifth step).

Thereafter, while the H₂ gas is supplied, the fifth gas supply source 184 supplies the Cl₂ gas to the processing chamber 201 as an etching gas (a second etching gas). To control desired gas flow, the opening of the MFC 189 is adjusted, and the valve 179 is opened to supply the Cl₂ gas to the upper portion of the processing chamber 201 through the gas supply pipe 232. The Cl₂ gas etches the second films formed on the silicon oxide films (insulation films) of the wafers 200 by the SiH₄ gas (S408, sixth step).

After a predetermined time interval, the valve 179 of the fifth gas supply source 184 is closed to cut off the Cl₂ gas, and the processing chamber 201 is purged with H₂ gas (S409, seventh step).

The steps 406 to 409 are repeated predetermined times. Thereafter, the inside of the processing chamber 201 is replaced with H₂ gas, and the pressure inside the processing chamber 201 returns to atmospheric pressure.

Thereafter, the lift motor 248 is operated to move down the seal cap 219 and open the lower end of the manifold 209, and the processed wafers 200 charged in the boat 130 are unloaded from the lower end of the manifold 209 to the outside of the outer tube 205. Then, the wafers 200 are discharged from the boat 130 (S410).

In the current embodiment, the processing conditions of wafers 200 in the processing furnace 202 as follows. For example, high-temperature silicon selective epitaxial films (first films) are formed at a temperature of 700° C. to 850° C., a SiH₂Cl₂ gas flow of 1 sccm to 1000 sccm, a HCl gas flow of 1 sccm to 1000 sccm, a H₂ gas flow of 10 sccm to 50000 sccm, and a processing pressure equal to or lower than 2000 pa. In changing from a first film forming temperature to a second film forming temperature, for example, an H₂ gas flow of 10 sccm to 50000 sccm, and a processing pressure equal to or lower than 2000 pa are given. For example, low-temperature silicon selective epitaxial films (second films) are formed at a temperature of 500° C. to 750° C., a SiH₄ gas flow of 1 sccm to 1000 sccm or a Cl₂ gas flow of 1 sccm to 1000 sccm, a H₂ gas flow of 10 sccm to 50000 sccm, and a processing pressure equal to or lower than 2000 pa. The processing conditions may be kept constant in each operation within the above-mentioned exemplary ranges.

In the case where SiH₄ gas and Cl₂ gas are simultaneously supplied for forming second films (low-temperature silicon selective epitaxial films), the second films may grow slowly due to a high etching ability of the Cl₂ gas. However, in the current embodiment, SiH₄ and Cl₂ gas are alternately supplied to prevent film formation by the SiH₄ gas from being disturbed by the Cl₂ gas. Therefore, as a whole, the second films can be formed rapidly and efficiently.

In the above-described embodiments 1 to 4, the steps can be combined to provide effects of the present invention. In the embodiments 1 to 4, forming an epitaxial film on a silicon substrate by using a vertical-type CVD apparatus is explained; however, the present invention can employ a substrate processing apparatus such as a horizontal-type or single-wafer type apparatus with no limitation to the type of apparatuses. In addition, the present invention is not limited to forming an epitaxial film but also applicable to various methods of forming a film on a substrate using chemical deposition, for example, forming a polysilicon film. In addition, the present invention is not limited to a film forming process on a silicon surface but also applicable to a film forming process on a silicon-germanium surface. In addition, each time after the first and second films are formed, H₂ gas is supplied to the processing chamber 201, and N₂ is preferably supplied to remove the remaining H₂ gas.

The step of forming a first film and the step of forming second step can be performed using separate apparatuses. Specifically, when the first film is formed at a relatively high temperature, the film forming rate is high, and thus the first film can be efficiently formed even with a single-wafer type processing apparatus. The second film is formed more rapidly than the first film. However, if the second film is thicker than the first film, since productivity decreases when the second film is formed using a single-wafer type processing apparatus, the second film may be preferably formed using a batch type processing apparatus capable of processing a plurality of substrates simultaneously.

According to another preferred embodiment of the present invention, in the above-described embodiment 3, there is provided a method for fabricating a semiconductor device, in which first and second films are formed in a processing chamber at a constant temperature of about 700° C.

According to another preferred embodiment of the present invention, in the above-described embodiments 1 to 4, there is provided a method for fabricating a semiconductor device, in which H₂ purging is performed after silane-based gas or etching gas is supplied.

According to another preferred embodiment of the present invention, in the above-described embodiment 1, 2, or 4, there is provided a method for fabricating a semiconductor device, in which a second film may be formed at a temperature lower than a temperature at which a first film is formed.

According to another preferred embodiment of the present invention, in the above-described embodiments 2 to 4, there is provided a method for fabricating a semiconductor device, in which when H₂ purging is performed after a first film is formed using a first silane-based gas and a first etching gas, at least the first silane-based gas of the first silane-based gas and the first etching gas is continuously supplied.

According to another preferred embodiment of the present invention, in the above-described embodiments 1 to 4, there is provided a method for fabricating a semiconductor device, in which H₂ gas is continuously supplied.

According to another preferred embodiment of the present invention, in the above-described embodiments 1 to 4, there is provided a method for fabricating a semiconductor device, in which selective epitaxial films are grown on a plurality of substrates simultaneously.

According to another preferred embodiment of the present invention, in the above-described embodiments 1 to 4, there is provided a method for fabricating a semiconductor device, in which N₂ purging is performed after H₂ purging.

According to the present invention, a film can be formed at a relatively high rate without etching an N⁺ substrate.

(Supplementary Note) The present invention also includes the following embodiments.

(Supplementary Note 1)

According to an embodiment of the present invention, there is provided a method for fabricating a semiconductor device, the method including: a first step of loading a substrate into a processing chamber; a second step of supplying at least a first silane-based gas and a first etching gas to the processing chamber while heating the substrate; and a third step of supplying at least a second silane-based gas and a second etching gas to the processing chamber while heating the substrate.

(Supplementary Note 2)

In the method of Supplementary Note 1, it is preferable that the second and third steps be performed when the processing chamber has a stable temperature.

(Supplementary Note 3)

In the method of Supplementary Note 2, it is preferable that the second and third steps be performed when the processing chamber has a temperature of about 700° C.

(Supplementary Note 4)

In the method of Supplementary Note 1, it is preferable that the processing chamber be purged with H₂ gas after each of the second and third steps.

The method of Supplementary Note 1, it is preferable that the processing chamber is changed in temperature for proceeding from the second step to the third step.

(Supplementary Note 5)

In the method of Supplementary Note 1, it is preferable that the third step be performed at a temperature lower than a temperature at which the second step is performed.

(Supplementary Note 6)

In the method of Supplementary Note 1, it is preferable that after the second step, the processing chamber be purged with H₂ gas while supplying the processing chamber with at least the first silane-based gas of the first silane-based gas and the first etching gas that are used in the second step.

(Supplementary Note 7)

In the method of Supplementary Note 1, it is preferable that the processing chamber be continuously supplied with H₂ gas.

(Supplementary Note 8)

In the method of Supplementary Note 1, it is preferable that the first silane-based gas, the first etching gas, the second silane-based gas, and the second etching gas be SiH₂Cl₂ gas, HCl gas, SiH₄ gas, and Cl₂ gas, respectively.

(Supplementary Note 9)

In the method of Supplementary Note 1, it is preferable that a film be formed on the substrate to a thickness of about 10 Å to about 2000 Å in the second step.

(Supplementary Note 10)

It is preferable that the method of Supplementary Note 1 be performed to grow selective epitaxial films on a plurality of substrates simultaneously.

(Supplementary Note 11)

In the method of Supplementary Note 1, it is preferable that the second step be performed using a single-wafer type processing apparatus, and the third step be performed using a batch type processing apparatus.

(Supplementary Note 12)

In the method of Supplementary Note 1, it is preferable that the processing chamber be purged with H₂ gas and then with N₂ gas.

(Supplementary Note 13)

According to another embodiment of the present invention, there is provided a method for fabricating a semiconductor device, the method including: a first step of loading a substrate into a processing chamber; a second step of supplying at least a first silane-based gas and a first etching gas to the processing chamber while heating the substrate; a third step of supplying at least a second silane-based gas to the processing chamber while heating the substrate; and a fourth step of supplying at least a second etching gas to the processing chamber while heating the substrate, wherein the third and fourth steps are repeated a plurality of times.

(Supplementary Note 14)

In the method of Supplementary Note 13, it is preferable that the second to fourth steps be performed when the processing chamber has a stable temperature.

(Supplementary Note 15)

In the method of Supplementary Note 14, it is preferable that the second to fourth steps be performed when the processing chamber has a temperature of about 700° C.

(Supplementary Note 16)

In the method of Supplementary Note 13, it is preferable that the processing chamber be purged with H₂ gas after each of the second to fourth steps.

(Supplementary Note 17)

In the method of Supplementary Note 13, it is preferable that the processing chamber be changed in temperature for proceeding from the second step to the third step.

(Supplementary Note 18)

In the method of Supplementary Note 13, it is preferable that the third step be performed at a temperature lower than a temperature at which the second step is performed.

(Supplementary Note 19)

In the method of Supplementary Note 13, it is preferable that after the second step, the processing chamber be purged with H₂ gas while supplying the processing chamber with at least the first silane-based gas of the first silane-based gas and the first etching gas that are used in the second step.

(Supplementary Note 20)

In the method of Supplementary Note 13, it is preferable that the processing chamber be continuously supplied with H₂ gas.

(Supplementary Note 21)

In the method of Supplementary Note 13, it is preferable that the first silane-based gas, the first etching gas, the second silane-based gas, and the second etching gas be SiH₂Cl₂ gas, HCl gas, SiH₄ gas, and Cl₂ gas, respectively.

(Supplementary Note 22)

In the method of Supplementary Note 13, it is preferable that a film be formed on the silicon substrate to a thickness of about 10 Å to about 2000 Å in the second step.

(Supplementary Note 23)

It is preferable that the method of Supplementary Note 13 be performed to grow selective epitaxial films on a plurality of substrates simultaneously.

(Supplementary Note 24)

In the method of Supplementary Note 13, it is preferable that the second step be performed using a single-wafer type processing apparatus, and the third and fourth steps be performed using a batch type processing apparatus.

(Supplementary Note 25)

In the method of Supplementary Note 13, it is preferable that the processing chamber be purged with H₂ gas and then with N₂ gas.

(Supplementary Note 26)

According to another embodiment of the present invention, there is provided a substrate processing apparatus including: a processing chamber configured to accommodate a substrate; a heater configured to heat the substrate; a plurality of gas supply units configured to supply silane-based gas and etching gas to the processing chamber; an exhaust unit configured to exhaust the processing chamber; and a controller configured to control the processing chamber, the heater, the gas supply units, and the exhaust unit, wherein the controller controls a first gas supply unit to supply a first silane-based gas and a first etching gas in a first step, and the controller controls a second gas supply unit to supply a second silane-based gas and a second etching gas in a second step.

(Supplementary Note 27)

In the substrate processing apparatus of Supplementary Note 26, it is preferable that the heater be controlled to keep the substrate at a first temperature in the first step and a second temperature in the second step.

(Supplementary Note 28)

In the substrate processing apparatus of Supplementary Note 26, it is preferable that the heater be controlled to keep the substrate at the same temperature in the first and second steps.

What is claimed is:

1. A method for fabricating a semiconductor device, the method comprising:
a first step of loading a substrate into a processing chamber;
a second step of supplying at least a first silane-based gas and a first etching gas to the processing chamber while heating the substrate; and
a third step of supplying at least a second silane-based gas and a second etching gas to the processing chamber while heating the substrate.

2. The method of claim 1, wherein the second and third steps are performed when the processing chamber has a stable temperature.

3. The method of claim 2, wherein the second and third steps are performed when the processing chamber has a temperature of about 700° C.

4. The method of claim 1, wherein the processing chamber is purged with H₂ gas after each of the second and third steps.
The method of claim 1, wherein the processing chamber is changed in temperature for proceeding from the second step to the third step.

5. The method of claim 1, wherein the third step is performed at a temperature lower than a temperature at which the second step is performed.

6. The method of claim 1, wherein after the second step, the processing chamber is purged with H₂ gas while supplying the processing chamber with at least the first silane-based gas of the first silane-based gas and the first etching gas that are used in the second step.

7. The method of claim 1, wherein the processing chamber is continuously supplied with H₂ gas.

8. The method of claim 1, wherein the first silane-based gas, the first etching gas, the second silane-based gas, and the second etching gas are SiH₂Cl₂ gas, HCl gas, SiH₄ gas, and Cl₂ gas, respectively.

9. The method of claim 1, wherein in the second step, a film is formed on the silicon substrate to a thickness of about 10 Å to about 2000 Å.

10. The method of claim 1, wherein the method is performed to grow selective epitaxial films on a plurality of substrates simultaneously.

11. The method of claim 1, wherein the second step is performed using a single-wafer type processing apparatus, and the third step is performed using a batch type processing apparatus.

12. The method of claim 1, wherein the processing chamber is purged with H₂ gas and then with N₂ gas.

13. A method for fabricating a semiconductor device, the method comprising:
a first step of loading a substrate into a processing chamber;
a second step of supplying at least a first silane-based gas and a first etching gas to the processing chamber while heating the substrate;
a third step of supplying at least a second silane-based gas to the processing chamber while heating the substrate; and
a fourth step of supplying at least a second etching gas to the processing chamber while heating the substrate,
wherein the third and fourth steps are repeated a plurality of times.

14. The method of claim 13, wherein the second to fourth steps are performed when the processing chamber has a stable temperature.

15. The method of claim 14, wherein the second to fourth steps are performed when the processing chamber has a temperature of about 700° C.

16. The method of claim 13, wherein the processing chamber is purged with H₂ gas after each of the second to fourth steps.

17. The method of claim 13, wherein the processing chamber is changed in temperature for proceeding from the second step to the third step.

18. The method of claim 13, wherein the third step is performed at a temperature lower than a temperature at which the second step is performed.

19. The method of claim 13, wherein after the second step, the processing chamber is purged with H₂ gas while supplying the processing chamber with at least the first silane-based gas of the first silane-based gas and the first etching gas that are used in the second step.

20. The method of claim 13, wherein the processing chamber is continuously supplied with H₂ gas.

21. The method of claim 13, wherein the first silane-based gas, the first etching gas, the second silane-based gas, and the second etching gas are SiH₂Cl₂ gas, HCl gas, SiH₄ gas, and Cl₂ gas, respectively.

22. The method of claim 13, wherein in the second step, a film is formed on the silicon substrate to a thickness of about 10 Å to about 2000 Å.

23. The method of claim 13, wherein the method is performed to grow selective epitaxial films on a plurality of substrates simultaneously.

24. The method of claim 13, wherein the second step is performed using a single-wafer type processing apparatus, and the third an fourth steps are performed using a batch type processing apparatus.

25. The method of claim 13, wherein the processing chamber is purged with H₂ gas and then with N₂ gas.

26. A substrate processing apparatus comprising:
a processing chamber configured to accommodate a substrate;
a heater configured to heat the substrate;
a plurality of gas supply units configured to supply silane-based gas and etching gas to the processing chamber;
an exhaust unit configured to exhaust the processing chamber; and
a controller configured to control the processing chamber, the heater, the gas supply units, and the exhaust unit,
wherein the controller controls a first gas supply unit to supply a first silane-based gas and a first etching gas in a first step, and the controller controls a second gas supply unit to supply a second silane-based gas and a second etching gas in a second step.

27. The substrate processing apparatus of claim 26, wherein the heater is controlled to keep the substrate at a first temperature in the first step and a second temperature in the second step.

28. The substrate processing apparatus of claim 26, wherein the heater is controlled to keep the substrate at the same temperature in the first and second steps.
